(19) United States
(12) Patent Application Publication
(10) Pub. No.: US 2007/0090346 A1
(43) Pub. Date: Apr. 26, 2007

(54) Porous chalcogenide thin film, method for preparing the same and electronic device using the same

(76) Inventors: Hyun Dam Jeong, Suwon-Si (KR); Jong Baek Seon, Seoul (KR); Hyeon Jin Shin, Suwon-Si (KR); Sang Heon Hyun, Suwon-Si (KR)

Correspondence Address: CANTOR COLBURN, LLP, 55 GRIFFIN ROAD SOUTH, BLOOMFIELD, CT, 06002, US

(21) Appl. No.: 11/439,036

(22) Filed: May 23, 2006

(30) Foreign Application Priority Data
Oct. 24, 2005 (KR) 2005-100131

(51) Int. Cl. C01G 11/02; H01L 29/08; C07F 3/00

(52) U.S. Cl. 257/40; 423/566.1; 257/E51.02; 546/2

(57) ABSTRACT

A porous chalcogenide thin film having a microporous structure, a method for preparing the chalcogenide thin film and an electronic device employing the chalcogenide thin film, are provided. The porous chalcogenide thin film has superior crystallinity and can be applied as a semiconductor layer having superior electrical properties to the fabrication of devices by inserting functional metal or semiconductor nanoparticles into nanopores of the thin film.

### BACKGROUND OF THE INVENTION

This non-provisional application claims priority under 35 U.S.C. §119(a) to Korean Patent Application No. 2005-100131 filed on Oct. 24, 2005, the entire contents of which are hereby incorporated by reference.

1. Field of the Invention

The present invention relates to a porous chalcogenide thin film, a method for preparing the thin film, and an electronic device that employs the thin film. More specifically, the present invention relates to a microporous chalcogenide thin film containing pores between 1 and 50 nanometers (nm) in size, a method for preparing the porous chalcogenide thin film using a chalcogenide precursor compound and a porogen that is soluble in organic solvents by a solution coating process, e.g., spin coating or dip coating, and a composition for use in the preparation of the chalcogenide thin film.

2. Description of the Related Art

Flat panel displays, such as liquid crystal displays and organic electroluminescent displays, include a number of thin film transistors (TFTS) for driving the devices. Thin film transistors comprise a gate electrode, source and drain electrodes, and a semiconductor layer activated depending on the driving of the gate electrode. A p-type or n-type semiconductor layer functions as a conductive channel material to facilitate the flow of current between the source and drain electrodes. The semiconductor layer is modulated by the applied gate voltages.

Semiconductor materials mainly used in thin film transistors are amorphous silicon (a-Si) and polycrystalline silicon (poly-Si). In recent years, a great deal of research has been conducted on organic semiconductor materials, such as pentacene and polythiophene.

Various attempts have been made to develop inorganic semiconductor materials, such as silicon-based semiconductor materials that are capable of covalent bonding. These can achieve high charge carrier mobility and can be prepared by low-cost processes, such as solution deposition processes, and other methods for preparing the semiconductor materials.

For example, thin film transistors have been proposed that comprise a cadmium sulfide (CdS) film deposited by a chemical bath deposition (CBD) method as a semiconductor active layer (DuPont, Thin Solid Films 444 (2003) 227-234). However, this deposition method suffers from problems of low deposition speed and disadvantageous applicability to processing arising from the use of a chemical bath.

Further, CdS thin films prepared by an electrostatic spray-assisted vapor deposition (ESAVD) technique have been suggested as window layers of heterojunction thin film photovoltaic cells (Thin Solid Films 359 (2000) 160-164). According to the ESAVD technique, charged aerogel is induced toward substrates by an applied electrostatic field without the use of a high-vacuum apparatus and hence the coating efficiency is advantageously improved. However, the ESAVD technique poses a problem in that the morphology of the thin films is non-uniform when compared with that of thin films prepared by spin coating.

U.S. Patent No. 6,875,661 and U.S. Patent Publication No. 2005/0009225 disclose methods for depositing a metal chalcogenide thin film using a precursor solution containing a metal chalcogenide and a hydrazine compound. The metal chalcogenide thin film is prepared by solution deposition. According to the methods, a soluble precursor solution comprising chalcogenide hydrazinium salt is first prepared, followed by spin coating to prepare the thin film. Since the chalcogenide hydrazinium salt is chemically unstable it tends to deteriorate when stored over a period of time. As a result, these methods are expensive and are not suitable for practical application to device fabrication lines.

On the other hand, nanoporous materials have drawn attention as materials for adsorbents, catalyst supports, thermal insulators and electrical insulators in various fields. Sol-gel processing employed in the preparation of gels, such as aerogels and zerogels are widely known as representative methods for forming porous structures of metal oxides. Aerogels are materials having a large specific surface area, a high porosity and a low density, and are prepared by drying a wet gel obtained through sol-gel processing under supercritical conditions where no gas-liquid interface exists so that the pore architecture of the wet gel remains unchanged. A zerogel is a liquid-free gel that is prepared by drying a wet gel by general heating. During drying of the zerogel, shrinkage of the gels commonly occurs due to the capillary pressure at the gas-liquid interfaces formed within pores to cause a change in the porous structure of the gels, leading to a decrease in surface area and pore volume. Based on the above characteristics inherent to aerogel, extensive research on aerogels is actively underway for a variety of applications, including thermal insulation and absorption, energy storage, catalysis, optics, and the like.

For example, porous semiconductor chalcogenide aerogels are suggested in Science 307 (2005), 397. The aerogels are prepared by capping chalcogenide nanoparticles with thiolates, gelling the capped nanoparticles, and drying the gel with supercritical carbon dioxide (CO₂). However, the chalcogenide nanoparticles serve to form a quantum dot array in the aerogels and are not electrically connected to each other. Accordingly, the aerogels are unsuitable for the fabrication of devices in which an electric current is required to flow.

Thus, there is a need to develop a porous chalcogenide thin film that has superior crystallinity and electrical properties and can be applied as an inorganic semiconductor layer to the fabrication of a variety of electronic devices, including thin film transistors.

### SUMMARY OF THE INVENTION

Therefore, the present invention provides a porous chalcogenide thin film having a microporous structure.

The present invention provides a method for the preparation of the chalcogenide thin film using a precursor solution containing a soluble chalcogenide precursor compound bound with a ligand and a porogen by a solution coating process, e.g., spin coating or dip coating, so that the electrical and physical properties (e.g., crystallinity) of the thin film are improved and a large-area coating is possible at reduced costs.

The present invention also provides a composition for preparing the porous chalcogenide thin film.

The present invention further provides a device using the chalcogenide thin film as a carrier transport layer.

In accordance with one aspect of the present invention, there is provided a porous chalcogenide thin film with a microporous structure that has greater crystallinity and can be applied as a semiconductor layer having superior electrical properties to the fabrication of devices by inserting functional metal nanoparticles, semiconductor nanoparticles or molecules into nanopores of the thin film.

In accordance with another aspect of the present invention, there is provided a method for preparing a porous chalcogenide thin film, the method comprising the steps of:

i) dissolving a chalcogenide precursor compound represented by Formula 1 below and a porogen in an organic solvent to prepare a precursor solution:

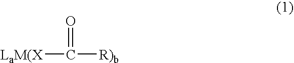

wherein L is selected from the group consisting of 2,3-lutidine, 2,4-lutidine, 2,5-lutidine, 2,6-lutidine, 3,4-lutidine, 3,5-lutidine, 3,6-lutidine, 2,6-lutidine-α²,3-diol, 2-hydroxypyridine, 3-hydroxypyridine, 4-hydroxypyridine, 2-hydroxyquinoline, 6-hydroxyquinoline, 8-hydroxyquinoline, 8-hydroxy-2-quinolinecarbonitrile, 8-hydroxy-2-quinolinecarboxylic acid, 2-hydroxy-4-(trifluoromethyl)pyridine, and N,N,N,N-tetramethylethylenediamine;

M is a metal atom selected from the group consisting of Group II, III and IV elements;

X is a Group VI chalcogen element;

R is hydrogen, substituted or unsubstituted C₁-C₃₀ alkyl, substituted or unsubstituted C₁-C₃₀ alkenyl, substituted or unsubstituted C₁-C₃₀ alkynyl, substituted or unsubstituted C₁-C₃₀ alkoxy, substituted or unsubstituted C₆-C₃₀ aryl, substituted or unsubstituted C₆-C₃₀ aryloxy, substituted or unsubstituted C₂-C₃₀ heteroaryl, substituted or unsubstituted C₂-C₃₀ heteroaryloxy, or substituted or unsubstituted C₂-C₃₀ heteroarylalkyl;

a is an integer from 0 to 2; and

b is 2 or 3,

ii) applying the precursor solution to a substrate, followed by primary annealing to prepare a thin film, and

iii) removing the porogen by secondary annealing of the thin film to form pores in the thin film.

In accordance with another aspect of the present invention, there is provided a composition for preparing the porous chalcogenide thin film comprising the chalcogenide precursor compound of Formula 1, a porogen and an organic solvent.

In accordance with yet another aspect of the present invention, there is provided a device comprising the chalcogenide thin film as a carrier transport layer.

### BRIEF DESCRIPTION OF THE DRAWINGS

The above features and other advantages of the present invention will be more clearly understood from the following detailed description taken in conjunction with the accompanying drawings, in which:

FIG. 1 is a diagram illustrating the procedure of a method for preparing a porous chalcogenide thin film according to the present invention;

FIG. 2 is a graph showing changes in the thickness of porous chalcogenide thin films prepared in Examples 1-4 and Comparative Example 1 as a function of the concentration of a porogen in the thin films;

FIG. 3 is a graph showing changes in the refractive index of porous chalcogenide thin films prepared in Examples 1-4 and Comparative Example 1 as a function of the concentration of a porogen in the thin films;

FIG. 4 is a cross-sectional transmission electron microscopy (TEM) image of a porous chalcogenide thin film prepared in Example 3 of the present invention;

FIGS. 5a and 5b are high-resolution transmission electron microscopy (TEM) images of a porous chalcogenide thin film prepared in Example 3 of the present invention;

FIG. 6 is an X-ray diffraction (XRD) pattern of a porous chalcogenide thin film prepared in Example 3 of the present invention; and

FIG. 7 is a graph showing the size of crystalline domains of porous chalcogenide thin films prepared in Examples 1-4 and Comparative Example 1 before and after removal of a porogen used to prepare the thin films as a function of the concentration of the porogen.

### DESCRIPTION OF THE PREFERRED EMBODIMENTS

The present invention will now be described in more detail with reference to the accompanying drawings.

The present invention provides a porous chalcogenide thin film characterized by having a microporous structure. The porous chalcogenide thin film contains pores having a size as small as from 1 to 50 nm. In one embodiment, the porous chalcogenide thin film contains pores having a size as small as from 2 to 45 nm. In another embodiment, the porous chalcogenide thin film contains pores having a size as small as from 5 to 40 nm. In yet another embodiment, the porous chalcogenide thin film contains pores having a size as small as from 10 to 35 nm. In yet another embodiment, the porous chalcogenide thin film contains pores having a size as small as from 15 to 30 nm.

The insertion of metal or semiconductor nanoparticles into the pores can effectively increase the electrical conductivity of the chalcogenide thin film, and hence, superior electrical properties can be provided to devices comprising the chalcogenide thin film.

The present invention also provides a method for preparing a porous chalcogenide thin film, the method comprising the steps of:

i) dissolving a chalcogenide precursor compound represented by Formula 1 below and a porogen in an organic solvent to prepare a precursor solution:

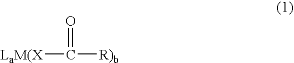

wherein L is selected from the group consisting of 2,3-lutidine, 2,4-lutidine, 2,5-lutidine, 2,6-lutidine, 3,4-lutidine, 3,5-lutidine, 3,6-lutidine, 2,6-lutidine-α²,3-diol, 2-hydroxypyridine, 3-hydroxypyridine, 4-hydroxypyridine, 2-hydroxyquinoline, 6-hydroxyquinoline, 8-hydroxyquinoline, 8-hydroxy-2-quinolinecarbonitrile, 8-hydroxy-2-quinolinecarboxylic acid, 2-hydroxy-4-(trifluoromethyl)pyridine, and N,N,N,N-tetramethylethylenediamine;

M is a metal atom selected from the group consisting of Group II, III and IV elements;

X is a Group VI chalcogen element;

R is hydrogen, substituted or unsubstituted C₁-C₃₀ alkyl, substituted or unsubstituted C₁-C₃₀ alkenyl, substituted or unsubstituted C₁-C₃₀ alkynyl, substituted or unsubstituted C₁-C₃₀ alkoxy, substituted or unsubstituted C₆-C₃₀ aryl, substituted or unsubstituted C₆-C₃₀ aryloxy, substituted or unsubstituted C₂-C₃₀ heteroaryl, substituted or unsubstituted C₂-C₃₀ heteroaryloxy, or substituted or unsubstituted C₂-C₃₀ heteroarylalkyl;

a is an integer from 0 to 2; and

b is 2 or 3,

ii) applying the precursor solution to a substrate, followed by primary annealing to prepare a thin film, and

iii) removing the porogen by secondary annealing of the thin film to form pores in the thin film.

Preferred compounds in Formula 1 are those wherein M is selected from the group consisting of cadmium (Cd), zinc (Zn), mercury (Hg), gallium (Ga), indium (In), lead (Pb) and tin (Sn), and X is selected from the group consisting of sulfur (S), selenium (Se) and tellurium (Te).

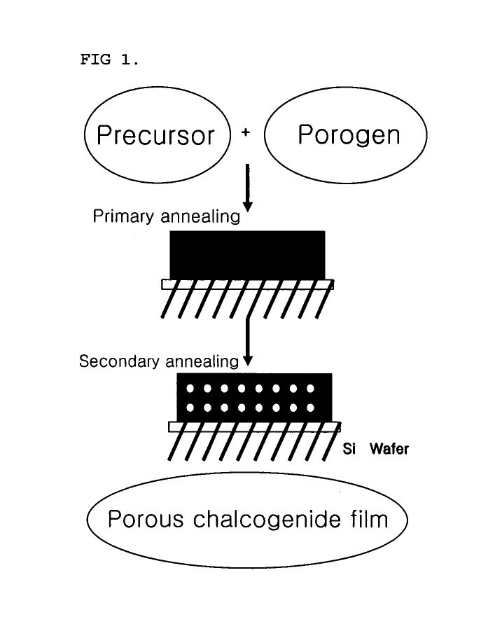

FIG. 1 shows the procedure of a method for preparing the porous chalcogenide thin film according to one embodiment of the present invention.

The porous structure of the porous chalcogenide thin film is formed using a porogen-template approach. The compound having the molecular structure of Formula 1 is used as a precursor to produce a matrix of the porous chalcogenide thin film, and a porogen, such as cyclodextrin, is used to facilitate the formation of pores within the matrix.

Generally, since inorganic lattices of thin films prepared from inorganic materials have extended covalent bonds, the charge carrier mobility can be significantly increased. Further, since inorganic materials are poorly soluble in organic solvents, it is possible to prepare high-quality films by solution coating processes. Due to the presence of ligands, such as lutidine, the solubility of the chalcogenide precursor compound in organic solvents is increased. This improves solution deposition thereby overcoming the problem of poor solubility of the chalcogenide.

The most preferred compound in Formula 1 is the chalcogenide wherein L is 3,5-lutidine, M is Cd, X is S, R is —CH₃, a is 2 and b is 2, which is represented by Formula 2 below:

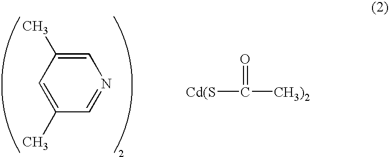

The precursor solution for use in the preparation of the porous chalcogenide thin film is a composition comprising the chalcogenide precursor compound, a porogen and an organic solvent.

The precursor solution may be prepared by mixing at least two different kinds of the chalcogenide precursor compound represented by Formula 1. The chalcogenide precursor compound of Formula 1 is preferably present in an amount of 0.1 to 50% by weight in the precursor solution.

The porogen used in the present invention can be selected from the group consisting of the following materials: α-cyclodextrin, β-cyclodextrin and γ-cyclodextrin; polyester, polystyrene, polyacrylate, polycarbonate and polyether; polynorbornene-based polymers; high-boiling point organic solvents, such as tetradecanes; polyalkylene oxide, polycaprolactone, poly(valeractone) and polymethyl methacrylate (PMMA); ionic surfactants, such as cetyltrimethylammonium bromide, cetyltetramethylammonium bromide, tetradecyl trimethylammonium bromide (TTAB) and dodecyl trimethylammonium bromide (DTAB); triblock copolymer-based non-ionic surfactants, such as polystyrene-oligo(p-phenylene ethynylene)-polystyrene, poly(propylene oxide)-poly(ethylene oxide)-poly(propylene oxide), poly(ethylene glycol)-b-poly(p-phenylene ethynylene)-b-poly(ethylene glycol), poly(2-ethyl-2-oxazoline)/poly(L-lactide) and poly(L-lactide)-block-poly(ethylene oxide)-block-poly(L-lactide); diblock copolymer-based non-ionic surfactants, such as poly(ethylene oxide)-b-poly(p-phenylene ethnylene), polystyrene/poly(ethylene oxide) copolymer, polystyrene-b-poly(methyl methacrylate) and poly(2-vinylpyridine)-block-poly((dimethylamino)ethyl methacrylate); tert-octyl phenyl polyoxyethylene ether (triton X-100); cethyl ether (Brij-56), or a combination comprising at least one of the foregoing. The porogen is removed by secondary annealing to leave pores. The amount of the porogen is preferably in the range of 0.1 to 30% by weight, based on the precursor solution.

Non-limiting examples of suitable organic solvents that can be used include aliphatic hydrocarbon solvents, such as hexane and heptane; aromatic hydrocarbon solvents, such as pyridine, quinoline, anisole, mesitylene and xylene; ketone-based solvents, such as methyl isobutyl ketone, 1-methyl-2-pyrrolidinone, cyclohexanone and acetone; ether-based solvents, such as tetrahydrofuran and isopropyl ether; acetate-based solvents, such as ethyl acetate, butyl acetate and propylene glycol methyl ether acetate; alcohol-based solvents, such as isopropyl alcohol and butyl alcohol; amide-based solvents, such as dimethylacetamide and dimethylformamide; silicon-based solvents; or a combination comprising at least one of the foregoing solvents.

The chalcogenide precursor solution thus prepared is applied to a substrate, followed by primary annealing to form a thin film. This primary annealing is carried out to cure the precursor solution and form an M-X network containing the porogen.

This is no limitation to the material of the substrate on which the chalcogenide thin film can be formed. Examples of suitable substrates include any substrate capable of withstanding heat-curing conditions, for example, glass substrates, silicon wafers, ITO glass, quartz, silica-coated substrates, alumina-coated substrates, and plastic substrates. These substrates can be selected according to intended applications.

The application of the chalcogenide precursor solution to the substrate may be carried out by a coating process, e.g., spin coating, dip coating, roll coating, screen coating, spray coating, spin casting, flow coating, screen printing, ink jet, or drop casting. In view of ease of application and uniformity, spin coating is most preferred as the coating process. Upon spin coating, the spin speed is preferably adjusted within the range of 100 to 10,000 rpm.

The primary annealing step includes the sub-steps of baking the precursor solution coated on the substrate and curing the precursor solution.

The baking is performed to evaporate the remaining organic solvent and dry the precursor solution. Due to the van der Waals attraction and the dipole-dipole interaction, packing occurs between the chalcogenide molecules. The baking can be performed by simply exposing the precursor solution to the atmosphere, subjecting the precursor solution to a vacuum during the initial stage or the subsequent stages of the curing process, or heating the precursor solution to a temperature of 50° C. to 100° C. in a nitrogen atmosphere for about one second to about five minutes.

Next, the curing is performed to thermally degrade and condense the bound ligand to form a hexagonal M-X structure. Specifically, the precursor solution is heat-cured in a nitrogen atmosphere at about 150 to about 600° C. for about 1 to about 60 minutes to form the final chalcogenide thin film. The curing can be performed by irradiating the precursor solution with UV light at 200 to 450 nm. The wavelength of the UV light may be varied within the range depending on the absorption wavelengths that the bound ligand and the metal absorb at.

The chalcogenide thin film undergoing the primary annealing is subjected to secondary annealing to remove the porogen, leaving pores in the thin film. The secondary annealing is preferably carried out under a vacuum at about 250 to about 600° C. for from 5 minutes to 2 hours.

The thickness and refractive index of the porous chalcogenide thin film prepared by this method may vary depending on the concentration of the porogen contained in the precursor solution. Even after the removal of the porogen through the first and secondary annealing processes, the hexagonal nanocrystal structure remains unchanged. Further, the size of the crystalline domains increases after removal of the porogen. If desired, metal or semiconductor nanoparticles may be inserted into the pores to allow the chalcogenide thin film to be used as a novel inorganic semiconductor layer having superior electrical properties in the fabrication of a variety of electronic devices.

Hereinafter, the present invention will be explained in more detail with reference to the following examples. However, these examples are given for the purpose of illustration and are not to be construed as limiting the scope of the invention.

### PREPARATIVE EXAMPLE 1

### Synthesis of Lut₂Cd(S(CO)CH₃)₂ (wherein Lut=3,5-lutidine)

First, 1.0 grams (g) (5.8 mmol) of cadmium carbonate, 1.2g (11.6 mmol) of 3,5-lutidine and 20 milliliters (ml) of toluene were mixed together in a round-bottom flask. 0.9 g (11.6 mmol) of thioacetic acid was added dropwise to the mixture with vigorous stirring. The resulting mixture was stirred at room temperature for one hour. As the reaction proceeded, the solid cadmium carbonate disappeared, CO₂ bubbling was observed, and the reaction solution turned yellow in color. The toluene and volatile reaction by-products were removed under reduced pressure to obtain a white crystalline solid and a small amount of a yellow solid, which is presumably cadmium sulfide. The solids were added to toluene, and filtered to remove the yellow solid. Next, the filtrate was placed in a freezer to obtain ca. 2.0-2.5 g of Lut₂Cd(S(CO)CH₃)₂ (yield: 59-74%) as a colorless crystal.

NMR Data

¹H NMR (C₆D₆): 1.69 [12H, CH₃-lutidine], 2.58 [6H, SOC CH₃], 6.55 [2H, lutidine para-CH], 8.50 [4H, lutidine ortho-CH]; ¹³C NMR: 17.8 [CH₃-lutidine], 35.1 [SOCCH₃], 133.7 [C—CH₃-lutidine], 138.8 [para-CH-lutidine], 147.7 [ortho-CH-lutidine]; ¹¹³Cd NMR: 353.5.

### EXAMPLE 1

First, 0.2 g of the chalcogenide precursor compound prepared in Preparative Example 1 and 0.02 g of a-cyclodextrin were dissolved in 1.8 g of pyridine. The solution was stirred to prepare a precursor solution for the preparation of a porous chalcogenide thin film. The coating solution was spin-coated at 500 revolutions per minute (rpm) on a 4 inch silicon wafer for 20 seconds, baked on a hot plate in a nitrogen atmosphere at 100° C. for one minute, and dried to obtain a film. The dried film was annealed in a nitrogen atmosphere at 200° C. for 5 minutes, and further annealed under a vacuum at 400° C. for one hour to prepare a porous chalcogenide thin film.

### EXAMPLES 2-4

Porous chalcogenide thin films were prepared in the same manner as in Example 1, except that 0.04 g, 0.06 g and 0.08 g of a-cyclodextrin each was used to prepare four precursor solutions.

### COMPARATIVE EXAMPLE 1

A porous chalcogenide thin film was prepared in the same manner as in Example 1, except that α-cyclodextrin was not used to prepare a precursor solution.

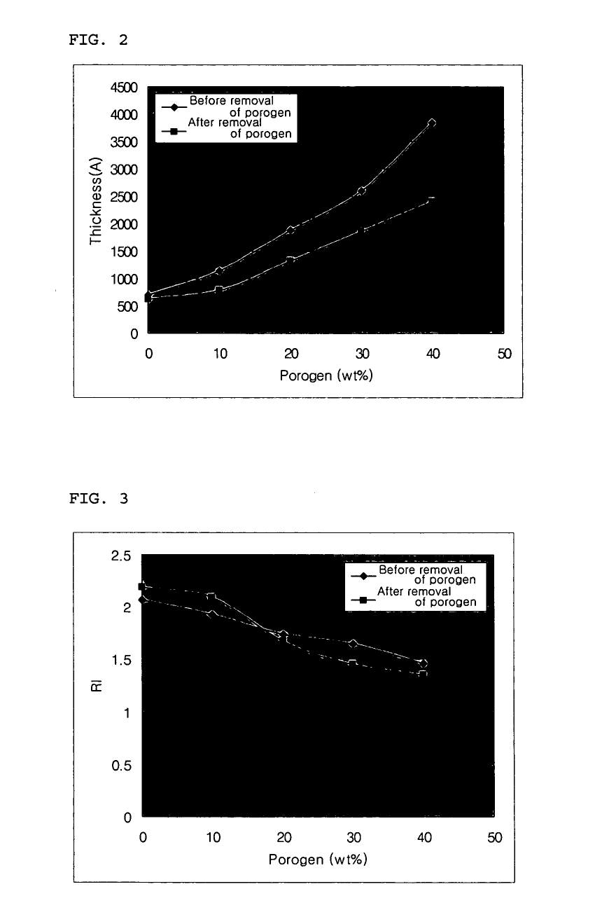

The thickness and refractive index of the porous chalcogenide thin films prepared in Examples 1-4 and Comparative Example 1 before and after removal of the porogen were measured depending on the concentration of the porogen in the thin films. The results are shown in FIGS. 2 and 3.

The graphs of FIGS. 2 and 3 show that the thickness of the thin films increases and the refractive index of the thin films decreases with increasing concentration of the porogen. The increase in the thickness reflects an increase in the volume of the film with the increase in the amount of porogen. The decrease in refractive index indicates an increase in the porosity of the thin films. The results confirm that the optical properties of the semiconductor thin films can be controlled by varying the concentration of the porogen used during preparation of the thin films.

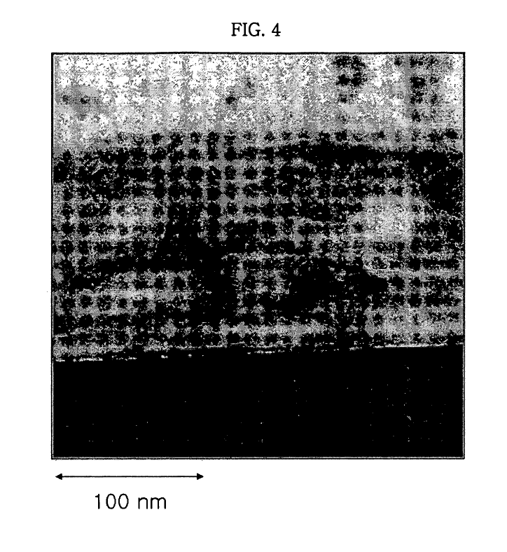

FIG. 4 is a cross-sectional transmission electron microscopy (TEM) image of the porous chalcogenide thin film prepared in Example 3. The image shown in FIG. 4 demonstrates that the CdS thin film formed on the silicon wafer has a porous structure (size: about 20 to about 50 Å).

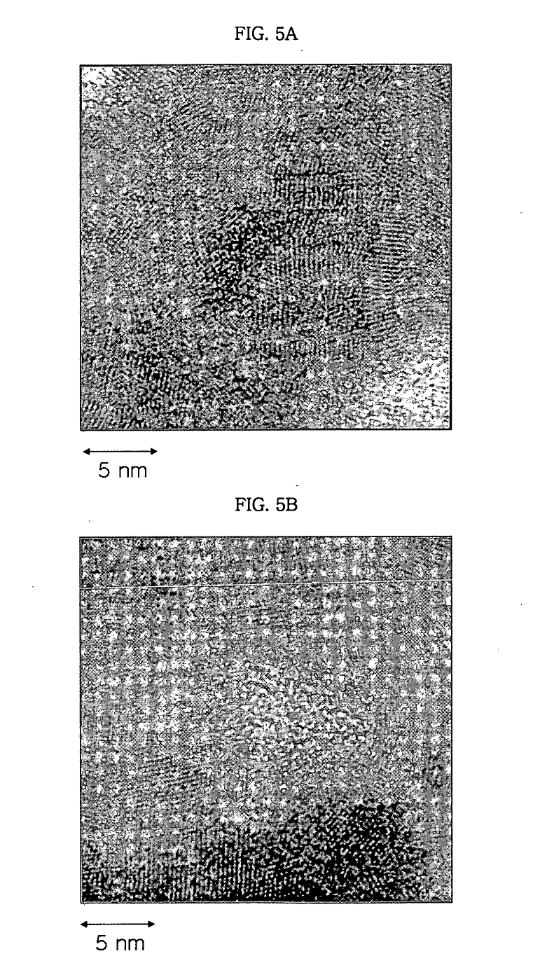

FIGS. 5a and 5b are high-resolution transmission electron microscopy (TEM) images of the porous chalcogenide thin film prepared in Example 3. The images show that nanocrystal domains having a diameter of 5 to 7 nm were formed in any direction and porous structures were formed.

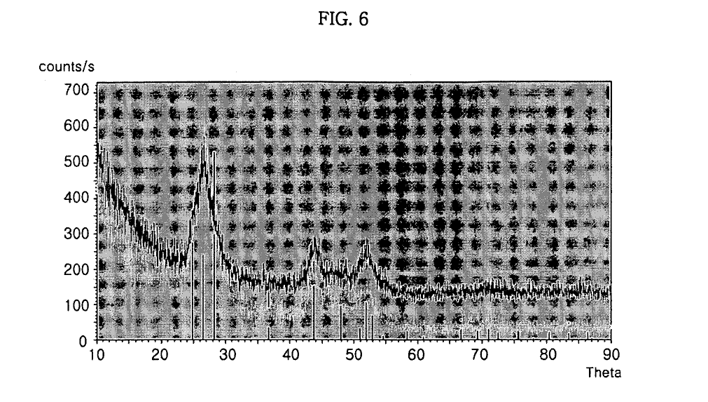

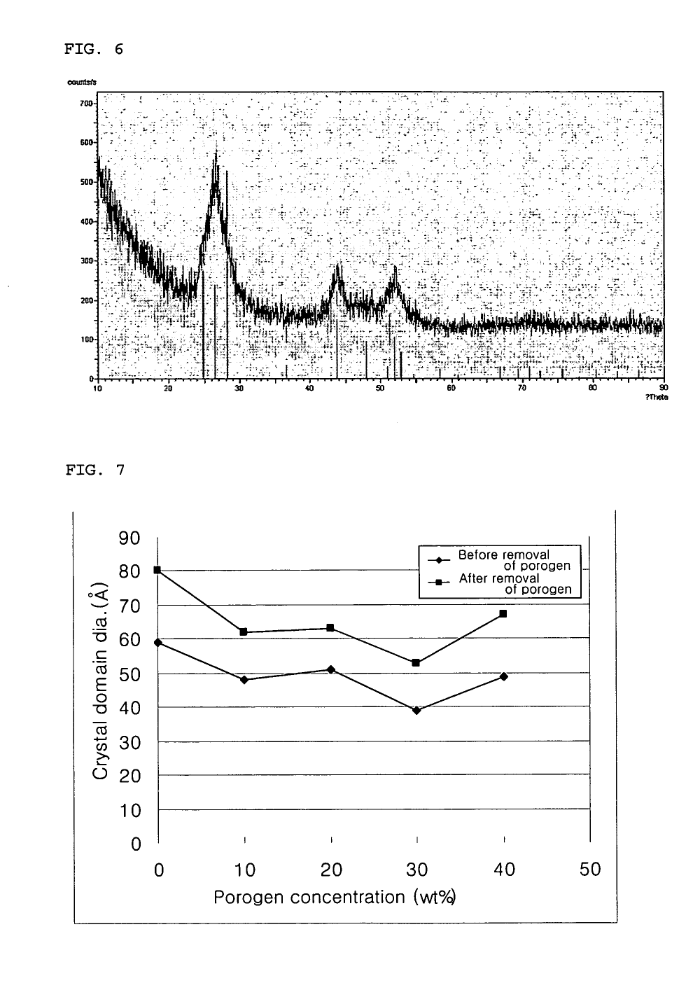

FIG. 6 shows an XRD pattern of the porous chalcogenide thin film prepared in Example 3. The CdS peaks shown in FIG. 6 reveal the formation of a hexagonal CdS nanocrystal before and after removal of the porogen.

The crystalline domain diameter of the porous chalcogenide thin films was measured from the full-width at half-maximum (FWHM) of the peak at 43.7° (2θ) in XRD patterns of the thin films. The results are shown in FIG. 7. The graph shown in FIG. 7 demonstrates that the crystalline domain diameter of the thin films using different porogen concentrations is larger after removal of the porogen than that before removal of the porogen.

The porous semiconductor thin films of the present invention using the chalcogenide compound exhibit superior physical properties, such as increased crystallinity, due to increased crystalline domains, and can be applied as semiconductor films having superior electrical properties by inserting metal or semiconductor nanoparticles into pores of the thin films. In addition, since the chalcogenide thin films can be prepared by a solution coating process, e.g., spin coating, they can be effectively applied to the fabrication of thin film transistors, electroluminescent devices, and photovoltaic cells.

As apparent from the above description, the porous semiconductor thin film with a microporous structure has superior crystallinity and can be applied as a semiconductor layer having superior electrical properties. It can further be used in the fabrication of devices by inserting functional metal or semiconductor nanoparticles into nanopores of the thin film. In addition, the use of an inorganic chalcogenide semiconductor material and a porogen soluble in organic solvents enables the preparation of the porous chalcogenide thin films over a large area by a solution coating process, e.g., spin coating or dip coating, thus contributing to a reduction in preparation costs.

The porous chalcogenide thin film of the present invention can be effectively utilized in a wide variety of applications, such as thin film transistors, electroluminescent devices, photovoltaic cells, and memory devices.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A porous chalcogenide thin film with a microporous structure.

2. The porous chalcogenide thin film according to claim 1, wherein the thin film contains pores having a size of 1 to 50 nm.

3. A method for preparing a porous chalcogenide thin film, the method comprising the steps of:
i) dissolving a chalcogenide precursor compound represented by Formula 1 below and a porogen in an organic solvent to prepare a precursor solution: 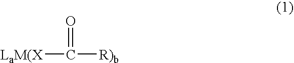
wherein L is selected from the group consisting of 2,3-lutidine, 2,4-lutidine, 2,5-lutidine, 2,6-lutidine, 3,4-lutidine, 3,5-lutidine, 3,6-lutidine, 2,6-lutidine-α²,3-diol, 2-hydroxypyridine, 3-hydroxypyridine, 4-hydroxypyridine, 2-hydroxyquinoline, 6-hydroxyquinoline, 8-hydroxyquinoline, 8-hydroxy-2-quinolinecarbonitrile, 8-hydroxy-2-quinolinecarboxylic acid, 2-hydroxy-4-(trifluoromethyl)pyridine, and N,N,N,N-tetramethylethylenediamine;
M is a metal atom selected from the group consisting of Group II, III and IV elements;
X is a Group VI chalcogen element;
R is hydrogen, substituted or unsubstituted C₁-C₃₀ alkyl, substituted or unsubstituted C₁-C₃₀ alkenyl, substituted or unsubstituted C₁-C₃₀ alkynyl, substituted or unsubstituted C₁-C₃₀ alkoxy, substituted or unsubstituted C₆-C₃₀ aryl, substituted or unsubstituted C₆-C₃₀ aryloxy, substituted or unsubstituted C₂-C₃₀ heteroaryl, substituted or unsubstituted C₂-C₃₀ heteroaryloxy, or substituted or unsubstituted C₂-C₃₀ heteroarylalkyl;
a is an integer from 0 to 2; and
b is 2 or 3,
ii) applying the precursor solution to a substrate, followed by primary annealing to prepare a thin film, and
iii) removing the porogen by secondary annealing of the thin film to form pores in the thin film.

4. The method according to claim 3, wherein M in the chalcogenide precursor compound of Formula 1 is selected from the group consisting of cadmium (Cd), zinc (Zn), mercury (Hg), gallium (Ga), indium (In), lead (Pb) and tin (Sn), and X is selected from the group consisting of sulfur (S), selenium (Se) and tellurium (Te).

5. The method according to claim 3, wherein the precursor compound of Formula 1 is represented by Formula 2 below:

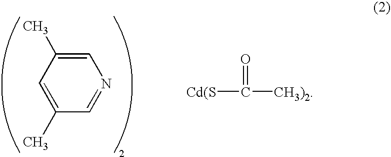

6. The method according to claim 3, wherein the precursor solution is prepared by mixing at least two different kinds of the chalcogenide precursor compound represented by Formula 1.

7. The method according to claim 3, wherein the porogen is selected from the group consisting of α-cyclodextrin, β-cyclodextrin, γ-cyclodextrin; polyester, polystyrene, polyacrylate, polycarbonate, polyether; polynorbornene-based polymers; organic solvents, tetradecanes; polyalkylene oxide, polycarprolactone, poly(valeractone), polymethyl methacrylate (PMMA); ionic surfactants, cetyltrimethylammonium bromide, cetyltetramethylammonium bromide, tetradecyl trimethylammonium bromide (TTAB) and dodecyl trimethylammonium bromide (DTAB); triblock copolymer-based non-ionic surfactants, polystyrene-oligo(p-phenylene ethynylene)-polystyrene, poly(propylene oxide)-poly(ethylene oxide)-poly(propylene oxide), poly(ethylene glycol)-b-poly(p-phenylene ethynylene)-b-poly(ethylene glycol), poly(2-ethyl-2-oxazoline)/poly(L-lactide), poly(L-lactide)-block-poly(ethylene oxide)-block-poly(L-lactide); diblock copolymer-based non-ionic surfactants, poly(ethylene oxide)-b-poly(p-phenylene ethnylene), polystyrene/poly(ethylene oxide) copolymer, polystyrene-b-poly(methyl methacrylate), poly(2-vinylpyridine)-block-poly((dimethylamino)ethyl methacrylate); tert-octyl phenyl polyoxyethylene ether; cethyl ether and combinations comprising at least one of the foregoing.

8. The method according to claim 3, wherein the chalcogenide precursor compound of Formula 1 is present in an amount of about 0.1 to about 50% by weight in the precursor solution.

9. The method according to claim 3, wherein the porogen is present in an amount of about 0.1 to about 30% by weight in the precursor solution.

10. The method according to claim 3, wherein the organic solvent is selected from the group consisting of aliphatic hydrocarbon solvents, hexane, heptane; aromatic hydrocarbon solvents, pyridine, quinoline, anisole, mesitylene, xylene; ketone-based solvents, methyl isobutyl ketone, 1-methyl-2-pyrrolidinone, cyclohexanone, acetone; ether-based solvents, tetrahydrofuran, isopropyl ether; acetate-based solvents, ethyl acetate, butyl acetate, propylene glycol methyl ether acetate; alcohol-based solvents, isopropyl alcohol, butyl alcohol; amide-based solvents, dimethylacetamide, dimethylformamide; silicon-based solvents; and a combination comprising at least one of the foregoing.

11. The method according to claim 3, wherein the precursor solution is applied to the substrate by spin coating, dip coating, roll coating, screen coating, spray coating, spin casting, flow coating, screen printing, ink jet, or drop casting.

12. The method according to claim 3, wherein the primary annealing step includes the sub-steps of: baking the precursor solution applied to the substrate; and curing the precursor solution.

13. The method according to claim 12, wherein the baking is performed in a nitrogen atmosphere at about 50 to about 100° C. for about 1 to about 5 minutes.

14. The method according to claim 12, wherein the curing is performed in a nitrogen atmosphere at about 150 to about 600° C. for about 1 to about 60 minutes.

15. The method according to claim 12, wherein the curing is performed by UV curing.

16. The method according to claim 3, wherein the secondary annealing is carried out under a vacuum at about 250 to about 600° C. for about 5 minutes to about 2 hours.

17. A composition for preparing a porous chalcogenide thin film comprising,
a chalcogenide precursor compound represented by Formula 1 below: 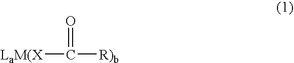
wherein L is selected from the group consisting of 2,3-lutidine, 2,4-lutidine, 2,5-lutidine, 2,6-lutidine, 3,4-lutidine, 3,5-lutidine, 3,6-lutidine, 2,6-lutidine-α²,3-diol, 2-hydroxypyridine, 3-hydroxypyridine, 4-hydroxypyridine, 2-hydroxyquinoline, 6-hydroxyquinoline, 8-hydroxyquinoline, 8-hydroxy-2-quinolinecarbonitrile, 8-hydroxy-2-quinolinecarboxylic acid, 2-hydroxy-4-(trifluoromethyl)pyridine, and N,N,N,N-tetramethylethylenediamine;
M is a metal atom selected from the group consisting of Group II, III and IV elements;
X is a Group VI chalcogen element;
R is hydrogen, substituted or unsubstituted C₁-C₃₀ alkyl, substituted or unsubstituted Cₗ-C₃₀ alkenyl, substituted or unsubstituted C₁-C₃₀ alkynyl, substituted or unsubstituted C₁-C₃₀ alkoxy, substituted or unsubstituted C₆-C₃₀ aryl, substituted or unsubstituted C₆-C₃₀ aryloxy, substituted or unsubstituted C₂-C₃₀ heteroaryl, substituted or unsubstituted C₂-C₃₀ heteroaryloxy, or substituted or unsubstituted C₂-C₃₀ heteroarylalkyl;
a is an integer from 0 to 2;
b is 2 or 3,
a porogen, and an organic solvent.

18. The composition according to claim 17, wherein the composition comprises about 0.1 to about 50% by weight of the chalcogenide precursor compound, about 0.1 to about 30% by weight of the porogen, and the remaining weight percent of the organic solvent.

19. An electronic device comprising the porous chalcogenide thin film according to claim 1 as a carrier transport layer.

20. An electronic device comprising the porous chalcogenide thin film according to claim 2 as a carrier transport layer.

21. The electronic device according to claim 19, wherein the electronic device is a thin film transistor, an electroluminescent device, a photovoltaic cell, or a memory device.

22. The electronic device according to claim 20, wherein the electronic device is a thin film transistor, an electroluminescent device, a photovoltaic cell, or a memory device.
